(19) United States
(12) Patent Application Publication
(10) Pub. No.: US 2013/0162833 A1
(43) Pub. Date: Jun. 27, 2013

(54) IMAGING APPARATUS, RADIATION IMAGING SYSTEM, AND METHOD FOR MANUFACTURING IMAGING APPARATUS

(71) Applicant: Canon Kabushiki Kaisha, Tokyo (JP)

(72) Inventors: Hiroshi Wayama, Saitama-shi (JP); Chiori Mochizuki, Sagamihara-shi (JP); Minoru Watanabe, Honjo-shi (JP); Keigo Yokoyama, Honjo-shi (JP); Masato Ofuji, Honjo-shi (JP); Jun Kawanabe, Kodama-gun (JP); Kentaro Fujiyoshi, Kumagaya-shi (JP)

(73) Assignee: Canon Kabushiki Kaisha, Tokyo (JP)

(21) Appl. No.: 13/683,182

(22) Filed: Nov. 21, 2012

(30) Foreign Application Priority Data
Dec. 21, 2011 (JP) 2011-279752

(51) Int. Cl. H04N 5/30; H01L 31/18; H01L 27/146

(52) U.S. Cl. CPC H04N 5/30; H01L 27/14643; H01L 31/18
USPC 348/162; 257/292; 438/73

(57) ABSTRACT

An imaging apparatus includes: a plurality of pixels each of which includes a conversion element and a first transistor of which one of a source and a drain is connected to the conversion element; and a second transistor which is shared by the plurality of pixels and has a gate connected respectively to the other of the source and the drain of the first transistor of each of the plurality of pixels. At least one among the gate, a source, a drain and a channel portion of the second transistor is formed to be extended over the plurality of pixels, and the conversion element is arranged over the first and second transistors.

### BACKGROUND OF THE INVENTION

1. Field of the Invention

The present invention relates to an imaging apparatus, a radiation imaging system, and a method for manufacturing the imaging apparatus.

2. Description of the Related Art

In recent years, a technology for manufacturing a liquid crystal panel using a TFT (thin film transistor) is used in an imaging apparatus such as a radiation imaging apparatus in which the TFT is combined with a semiconductor conversion element. In the imaging apparatus, a technique is proposed which uses a source follower circuit (SFTFT) when reading a signal accumulated in the semiconductor conversion element to a signal line (see Japanese Patent Application Laid-Open No. 2006-345330).

### SUMMARY OF THE INVENTION

However, in the case in which the source follower circuit is applied to an imaging apparatus, when the signal is read, the delay corresponding to a time constant occurs which is defined by a product of the resistance of the source follower circuit and the wiring capacitance of the signal line. In the case of the radiation imaging apparatus, the size is approximately 40 cm×40 cm, the time constant is extremely large, and the speed of reading the signal results in not being sufficiently adequate. Thus, in a method of reading the signal in Japanese Patent Application Laid-Open No. 2006-345330, the speed of reading the signal causes the delay due to the resistance that the source follower circuit has, which causes a large problem, particularly, in high-speed driving.

The present invention is designed with respect to the above described problems, and provides a highly reliable imaging apparatus and radiation imaging system which enhances the speed of reading the signal even when the signal is transferred by the source follower circuit and can sufficiently cope with the high-speed driving as well, and a method for manufacturing the imaging apparatus.

According to an aspect of the present invention, an imaging apparatus comprises: a plurality of pixels, each including a conversion element and a first transistor, wherein one of a source and a drain of the first transistor is connected to the conversion element; and a second transistor being shared by the plurality of pixels and having a gate connected respectively to the other of the source and the drain of the first transistor of each of the plurality of pixels, wherein, at least one among the gate, a source, a drain and a channel portion of the second transistor is formed to be extended over the plurality of pixels, and the conversion element is arranged over the first and second transistors.

According to a further aspect of the present invention, a radiation imaging system comprises: the above described imaging apparatus; and a signal processing unit for processing a signal outputted from the imaging apparatus.

According to a still further aspect of the present invention, provided thereby is a manufacturing method of an imaging apparatus comprising: a plurality of pixels, each including a conversion element and a first transistor, wherein one of a source and a drain of the first transistor is connected to the conversion element, wherein the method comprising steps of: forming a second transistor being shared by the plurality of pixels and having a gate connected respectively to the other of the source and the drain of the first transistor of each of the plurality of pixels, such that at least one among the gate, a source, a drain and a channel portion of the second transistor is extended over the plurality of pixels; and forming the conversion element over the first and second transistors.

Further features of the present invention will become apparent from the following description of exemplary embodiments with reference to the attached drawings.

### BRIEF DESCRIPTION OF THE DRAWINGS

FIG. 1 is a circuit diagram illustrating a whole equivalent circuit of a radiation imaging apparatus according to a first embodiment, in a simple way.

FIG. 2 is a magnified layout chart illustrating two adjacent pixel regions in the radiation imaging apparatus according to the first embodiment.

FIG. 3 is a layout chart illustrating a manufacturing process of the radiation imaging apparatus according to the first embodiment.

FIG. 4 is a layout chart which follows FIG. 3 and illustrates a manufacturing process of the radiation imaging apparatus according to the first embodiment.

FIG. 5 is a layout chart which follows FIG. 4 and illustrates a manufacturing process of the radiation imaging apparatus according to the first embodiment.

FIG. 6 is a layout chart which follows FIG. 5 and illustrates a manufacturing process of the radiation imaging apparatus according to the first embodiment.

FIG. 7 is a layout chart which follows FIG. 6 and illustrates a manufacturing process of the radiation imaging apparatus according to the first embodiment.

FIG. 8 is a layout chart which follows FIG. 7 and illustrates a manufacturing process of the radiation imaging apparatus according to the first embodiment.

FIG. 9 is a layout chart which follows FIG. 8 and illustrates a manufacturing process of the radiation imaging apparatus according to the first embodiment.

FIG. 10 is a layout chart which follows FIG. 9 and illustrates a manufacturing process of the radiation imaging apparatus according to the first embodiment.

FIGS. 11A and 11B are layout charts including the cross section of FIG. 10.

FIG. 12 is a magnified layout chart illustrating N pieces of adjacent pixel regions in the radiation imaging apparatus according to a second embodiment.

FIG. 13 is a layout chart illustrating a manufacturing process of the radiation imaging apparatus according to the second embodiment.

FIG. 14 is a layout chart which follows FIG. 13 and illustrates a manufacturing process of the radiation imaging apparatus according to the second embodiment.

FIG. 15 is a layout chart which follows FIG. 14 and illustrates a manufacturing process of the radiation imaging apparatus according to the second embodiment.

FIG. 16 is a layout chart which follows FIG. 15 and illustrates a manufacturing process of the radiation imaging apparatus according to the second embodiment.

FIG. 17 is a layout chart which follows FIG. 16 and illustrates a manufacturing process of the radiation imaging apparatus according to the second embodiment.

FIG. 18 is a layout chart which follows FIG. 17 and illustrates a manufacturing process of the radiation imaging apparatus according to the second embodiment.

FIG. 19 is a layout chart which follows FIG. 18 and illustrates a manufacturing process of the radiation imaging apparatus according to the second embodiment.

FIGS. 20A and 20B are layout charts including the cross section of FIG. 19.

FIG. 21 is a representative layout chart of a radiation imaging apparatus according to a third embodiment.

FIG. 22 is a layout chart for describing a function of the radiation imaging apparatus according to the third embodiment of FIG. 21.

FIG. 23 is a schematic view illustrating a schematic configuration of an X-ray diagnosis system according to a fourth embodiment.

### DESCRIPTION OF THE EMBODIMENTS

Preferred embodiments of the present invention will now be described in detail in accordance with the accompanying drawings.

Embodiments of the present invention will be specifically described below with reference to the attached drawings. Incidentally, in the present application, an electro-magnetic wave means radioactive rays having a wavelength in a wavelength region from light such as visible light and infrared light to X-rays, α rays, β rays, γ rays and the like.

### First Embodiment

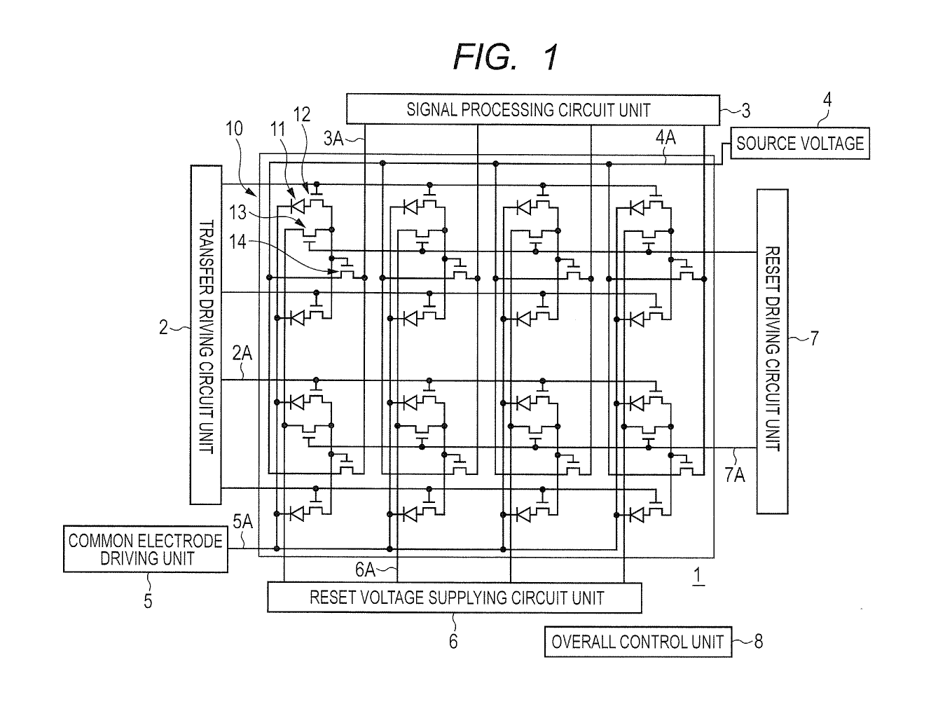

The present embodiment discloses a radiation imaging apparatus as an imaging apparatus. FIG. 1 is a circuit diagram illustrating a whole equivalent circuit of the radiation imaging apparatus according to the present embodiment, in a simple way.

This radiation imaging apparatus is illustrated by an example of an indirect type of radiation imaging apparatus, which converts an electro-magnetic wave into an electro-magnetic wave having another wavelength and then indirectly converts the electro-magnetic wave into an electrical signal, but may also be illustrated by an example of a direct type of radiation imaging apparatus, which directly converts the electro-magnetic wave into the electrical signal. In the direct type of radiation imaging apparatus, a so-called wavelength conversion element (GOS, CsI or the like) becomes unnecessary, which is different from the indirect type of radiation imaging apparatus. The radiation imaging apparatus has a plurality of pixel regions 10 arranged on a glass substrate 1 in a matrix form, and includes a transfer driving circuit unit 2, a signal processing circuit unit 3, a source voltage 4, a common electrode driving circuit unit 5, a reset voltage supplying circuit unit 6, a reset driving circuit unit 7 and an overall control unit 8.

For information, in addition to the structure of FIG. 1, a selection driving circuit unit may be provided, to which a selection thin film transistor is connected. The selection thin film transistor can more arbitrarily set a driving timing, and furthermore has a function of intercepting a leakage current which flows into a signal line 3A from a source follower thin film transistor 14.

The pixel region 10 includes a photoelectric conversion element 11, a transfer thin film transistor (first transistor) 12, and a reset thin film transistor 13. In addition, the source follower thin film transistor 14 (second transistor) that is common in the two adjacent pixel regions 10 is connected to the plurality of the pixel regions 10, which is two adjacent pixel regions 10 in the present embodiment.

The transfer driving circuit unit 2 has transfer driving lines 2A each of which is connected to each gate of the transfer thin film transistors 12 in each row in pixel regions 10, which are aligned in a row direction, and drives the transfer thin film transistors 12. The signal processing circuit unit 3 has signal lines 3A each of which is connected to each source of the source follower thin film transistors 14 in each column, which are aligned in the column direction, and performs the signal processing. The source voltage 4 has source voltage supply lines 4A each of which is connected to each drain of the source follower thin film transistors 14 in each row, which are aligned in the row direction, and supplies a drain voltage to the thin film transistors. The common electrode driving circuit unit 5 has common electrode lines 5A each of which is connected to photoelectric conversion elements 11 that are aligned in the column direction, and drives the photoelectric conversion elements 11. The reset voltage supplying circuit unit 6 has reset potential supply lines 6A each of which is connected to the reset thin film transistors 13 in each column, which are aligned in the column direction, and drives the reset thin film transistors 13. The reset driving circuit unit 7 has reset driving lines 7A each of which is connected to each gate of the reset thin film transistors 13 in each row, which are aligned in the row direction, and drives the reset thin film transistors 13.

The overall control unit 8 includes a central processing circuit (CPU), ROM and RAM, is connected to each of the transfer driving circuit unit 2, the signal processing circuit unit 3, the source voltage 4, the common electrode driving circuit unit 5, the reset voltage supplying circuit unit 6 and the reset driving circuit unit 7, and drives and controls the units. Incidentally, FIG. 1 omits the illustration of connection wires between the overall control unit 8 and each of the transfer driving circuit unit 2 to the reset driving circuit unit 7, for convenience in illustration.

Incidentally, the functions of each component (overall control unit 8 and the like) constituting the radiation imaging apparatus according to the present embodiment can be realized when a program stored in the RAM, the ROM or the like of the computer built in the radiation imaging apparatus works.

The photoelectric conversion element 11 is illustrated by an example of a so-called PIN type formed of a p-type semiconductor/semiconductor/n-type semiconductor, but may also be a so-called MIS type formed of a metal/insulating film/semiconductor. The transfer thin film transistor 12, the reset thin film transistor 13, and the source follower thin film transistor 14 are each illustrated by an example of a transistor using polysilicon, but may be formed of amorphous silicon. In addition, the form of each of the thin film transistors is illustrated by an example of a form of a top gate, but may be a form of a bottom gate.

As for the pixel region 10, FIG. 1 illustrates only a matrix of 4 pixel×4 pixel, but the number of the pixel regions 10 is arbitrary. In the present embodiment, one source follower thin film transistor 14 is arranged in each two adjacent pixel regions 10 in parallel with a signal line 3A. The gate of the source follower thin film transistor 14 is connected to a source or a drain of each of the transfer thin film transistors 12 in the two adjacent pixel regions 10, and the gate (channel portion) is formed so as to be extended over the two pixel regions 10. Not only the two pixel regions 10 but also the three or more pixel regions 10 may share one source follower thin film transistor 14, and the gate (channel portion) may also be formed so as to be extended over the three or more pixel regions 10.

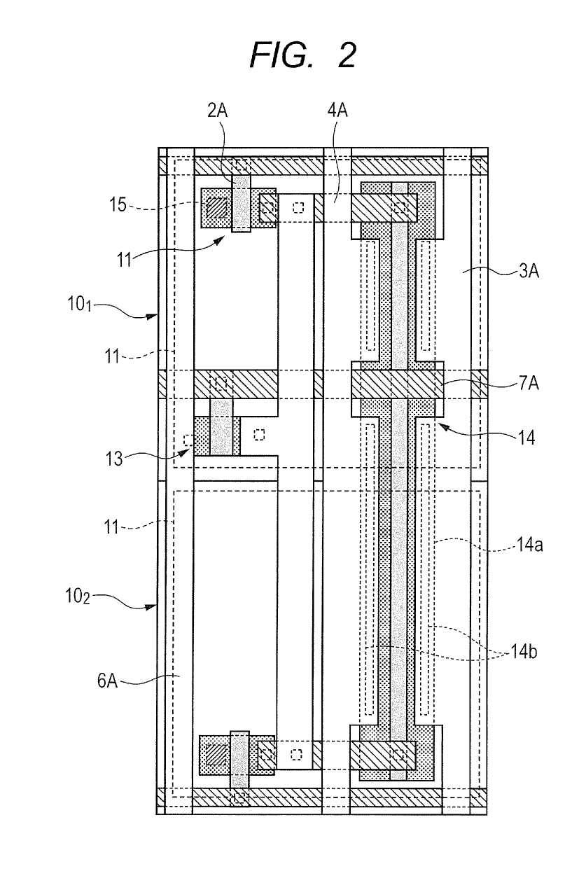

FIG. 2 is a magnified layout chart illustrating two adjacent pixel regions in the radiation imaging apparatus according to the present embodiment. Here, the respective pixel regions shall be represented by pixel regions 10₁ and 10₂. One source follower thin film transistor 14 is formed so as to be common in the pixel regions 10₁ and 10₂. One source follower thin film transistor 14 is arranged so that the gate 14a (and channel portion in lower part) and the source/drain 14b of the source follower thin film transistor 14 are extended over the pixel regions 10₁ and 10₂. In FIG. 2, each contact hole 15 is illustrated.

The radiation imaging apparatus usually has a rectangular shape with its one side of approximately 20 cm to 45 cm (for instance, approximately 40 cm×40 cm), and accordingly the length of the signal line 3A is also approximately 20 cm to 45 cm. In this case, the parasitic capacitance of the signal line of the signal processing circuit unit becomes approximately 50 pF to 300 pF. In addition, the electrical resistance of the thin film transistor to be used as the source follower thin film transistor usually becomes 10 kΩ to 100 kΩ, when the transistor is prepared from polysilicon, and becomes approximately 1 MΩ to 10 MΩ when the transistor is prepared from amorphous silicon. A transfer time constant is expressed by a product of the resistance value of the source follower thin film transistor and the resistance value of the signal line, and becomes such an extremely large value as approximately 1μ second to 500μ seconds, in the above described case. It is difficult to realize driving for a moving image by a transfer speed corresponding to the transfer time constant. In order to realize the enhancement of the transfer speed, there is no other way except to lower the resistance of the source follower thin film transistor or lower the parasitic capacitance of the signal line. It is equivalent to reducing the size of the radiation imaging apparatus to largely decrease the parasitic capacitance of the signal line, and is impossible. Accordingly, the resistance of the source follower thin film transistor should be decreased.

For this purpose, the source follower thin film transistor may be formed so as to be extended over the plurality (in the present embodiment, two) of the pixel regions. In the present embodiment, as is illustrated in FIG. 2, the source follower thin film transistor 14 is arranged so as to be extended over the pixel regions 10₁ and 10₂. This structure results in allowing the source follower thin film transistor 14 to have an extremely large channel width (gate width). The resistance value of the source follower thin film transistor is generally inversely proportional to the channel width. In other words, the source follower thin film transistor 14 of the present embodiment has twice as large channel width as the maximum width of a channel which can be formed in the one pixel region, by being extended over the plurality of the pixel regions, and accordingly the resistance value becomes a half of the value. Furthermore, when the source follower thin film transistor is formed so as to be extended over desired three or more pixel regions, an arbitrarily large channel width can be realized, which can sufficiently decrease the resistance value.

In addition, if the flexibility of the layout for the radiation imaging apparatus is enhanced, not only the channel width is enlarged, but also the channel area (channel width×source-drain space) of the source follower thin film transistor 14 can be greatly increased. In the source follower thin film transistor, a fluctuation (1/f) noise is generally a dominant component of a noise, and this 1/f noise is inversely proportional to the channel area. When the source follower thin film transistor is formed so as to be extended over the plurality of the pixel regions, the greatly increased channel width and the greatly increased channel area are obtained, and the low resistance and the low noise are realized.

FIG. 3 to FIG. 10 are layout charts illustrating a manufacturing process of the radiation imaging apparatus according to the present embodiment, in order of the steps. Here, only the two adjacent pixel regions 10₁ and 10₂ are illustrated.

Firstly, as is illustrated in FIG. 3, a buffer layer 22 is formed on a cleaned insulation substrate 21. This buffer layer 22 is formed of a silicon oxide film (SiO₂) or a silicon nitride film (SiN). The film thickness is desirably approximately 200 nm. Next, amorphous silicon 23 is film-formed on the buffer layer 22 with a plasma CVD method or the like. The film thickness is desirably approximately 50 nm to 200 nm. After the film has been formed, the amorphous silicon 23 is crystallized with a laser annealing method, and polysilicon 24 is formed. Next, this polysilicon is etched into an island shape so as to leave only a necessary portion.

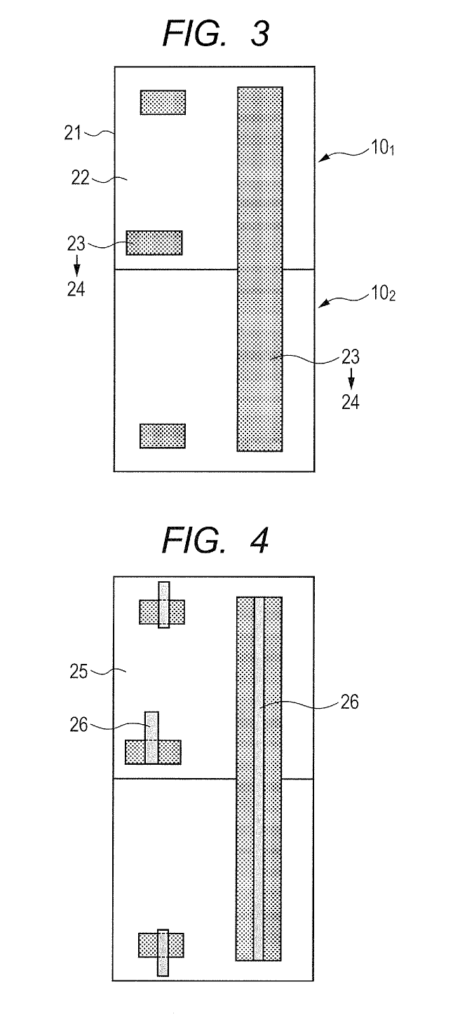

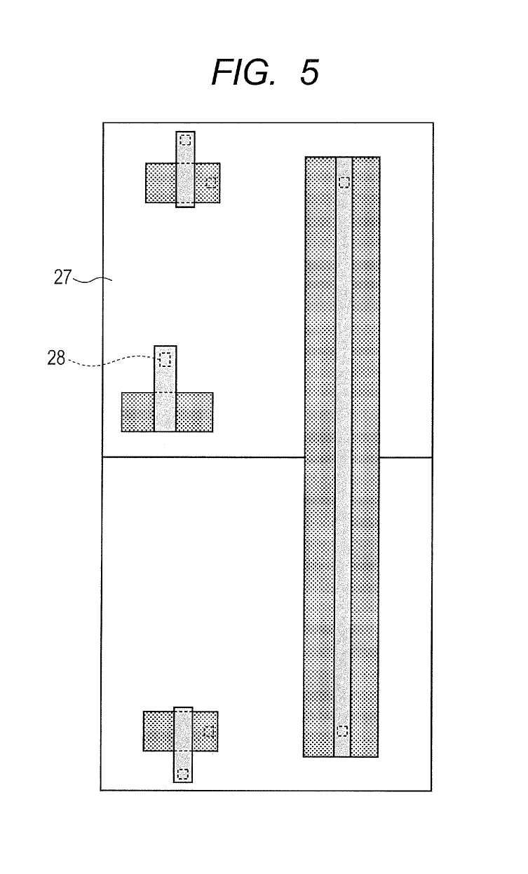

Subsequently, as is illustrated in FIG. 4, a gate insulation film 25 is formed, and a high-melting-point metal 26 is film-formed. The gate insulation film 25 desirably has a film thickness of approximately 50 nm to 200 nm. In addition, molybdenum, tungsten, an alloy thereof or the like may be used for the high-melting-point metal 26. After that, the high-melting-point metal 26 is patterned into an island shape by wet etching. After that, the polysilicon 24 is doped with ion while using the high-melting-point metal 26 as a mask. In addition, in this process, an impurity layer of semiconductors is formed, which becomes respective sources/drains of the transfer thin film transistor 12, the reset thin film transistor 13 and the source follower thin film transistor 14. At this time, there is also the case in which an LDD region (that is abbreviation for Lightly Doped Drain and has function of alleviating electric field between source and drain) is formed in order to suppress a leakage current flowing from each of the thin film transistors 12 to 14 or to enhance the characteristics thereof.

Subsequently, as is illustrated in FIG. 5, a first interlayer insulation film 27 is formed. The film thickness is desirably approximately 300 nm to 600 nm. After that, each contact hole 28 is formed in the first interlayer insulation film 27 by using a dry etching technology.

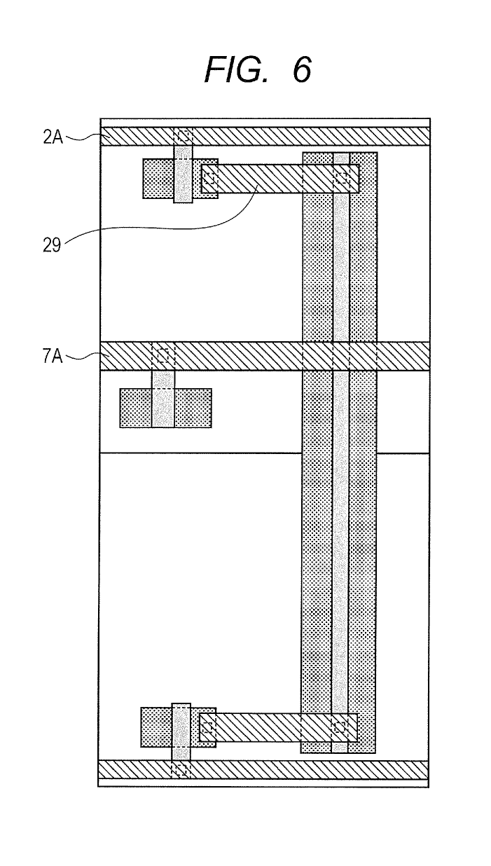

Subsequently, as is illustrated in FIG. 6, a first low-resistance metal layer 29 is film-formed. After that, the first low-resistance metal layer 29 is patterned with an etching technology, and a transfer driving line 2A and a reset driving line 7A are formed. An electroconductive material having as low resistance as possible is satisfactory for the first low-resistance metal layer 29. The film thickness is desirably approximately 300 nm to 700 nm.

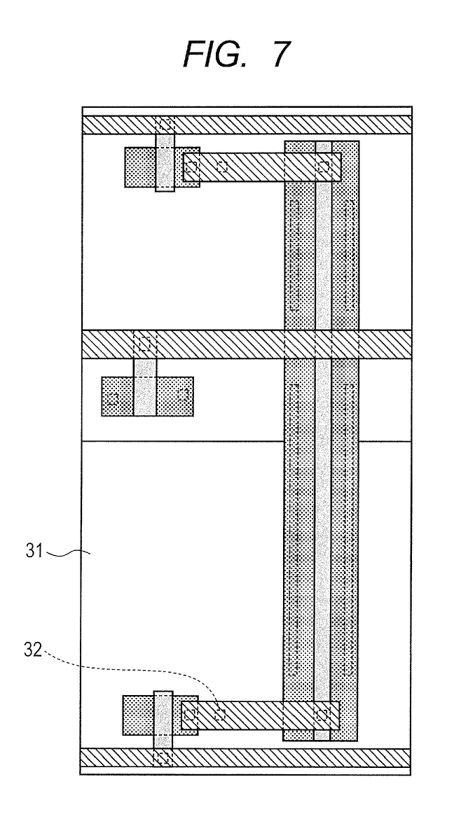

Subsequently, as is illustrated in FIG. 7, a second interlayer insulation film 31 is formed. After that, each contact hole 32 is formed in the second interlayer insulation film 31 by using a dry etching technology.

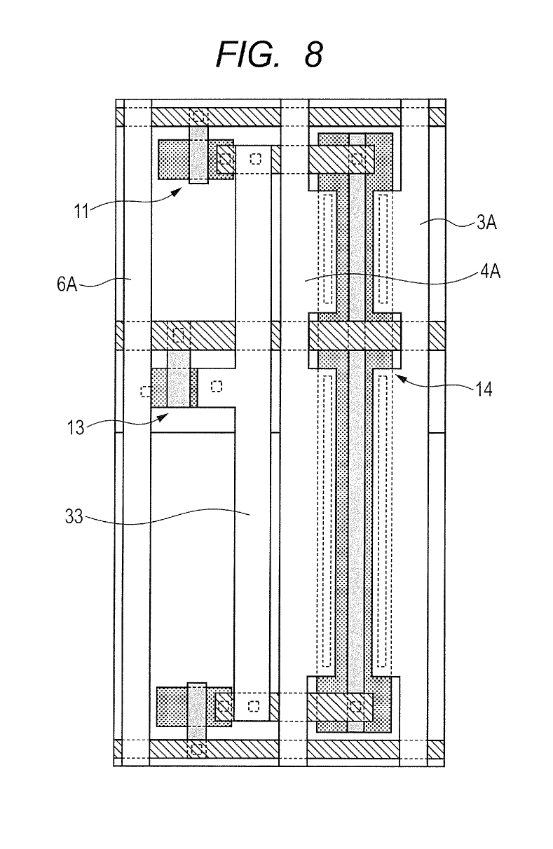

Subsequently, as is illustrated in FIG. 8, a second low-resistance metal layer 33 is film-formed. After that, the second low-resistance metal layer 33 is patterned with an etching technology, and a signal line 3A, a source voltage supply line 4A, a reset potential supply line 6A and the like are formed. By the above steps, the transfer thin film transistor 12, the reset thin film transistor 13 and the source follower thin film transistor 14 are formed.

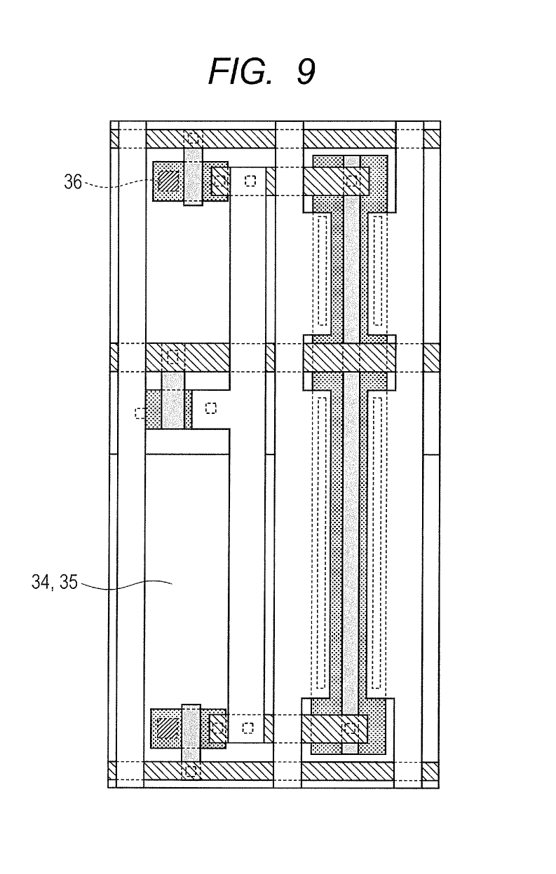

Subsequently, as is illustrated in FIG. 9, an interlayer insulation film 34 is formed, in order to protect these thin film transistors 12, 13 and 14, and an organic planarized film 35 is further formed thereon. The interlayer insulation film 34 may have a film thickness of approximately 500 nm, and the organic planarized film 35 may have a film thickness of approximately 3 μm to 5 μm in order to decrease the parasitic capacitance between the signal lines and a photoelectric conversion element which will be film-formed later. After that, a contact hole 36 for connecting the drain of the transfer thin film transistor 12 with the photoelectric conversion element is formed in the organic planarized film 35 and the interlayer insulation film 34.

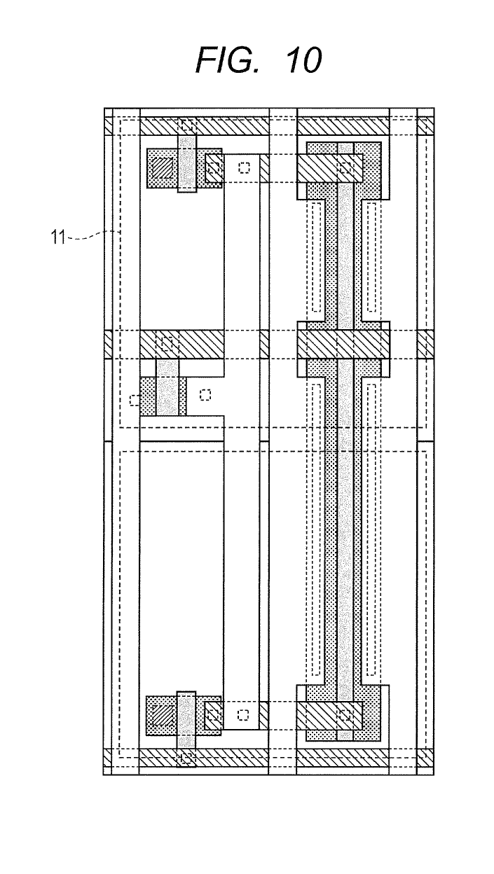

Subsequently, as is illustrated in FIG. 10, a material of the photoelectric conversion element is film-formed, the film is separated on a space between the pixel regions by etching, and the photoelectric conversion element 11 is formed. A common electrode line 5A and the like are connected to the photoelectric conversion element 11. The photoelectric conversion element 11 is formed of the PIN type. In addition, a protection film such as SiN, and a GOS or CsI which is a wavelength conversion element are arranged on the photoelectric conversion element 11.

By the above steps, the radiation imaging apparatus having a layout illustrated in FIG. 2 is formed.

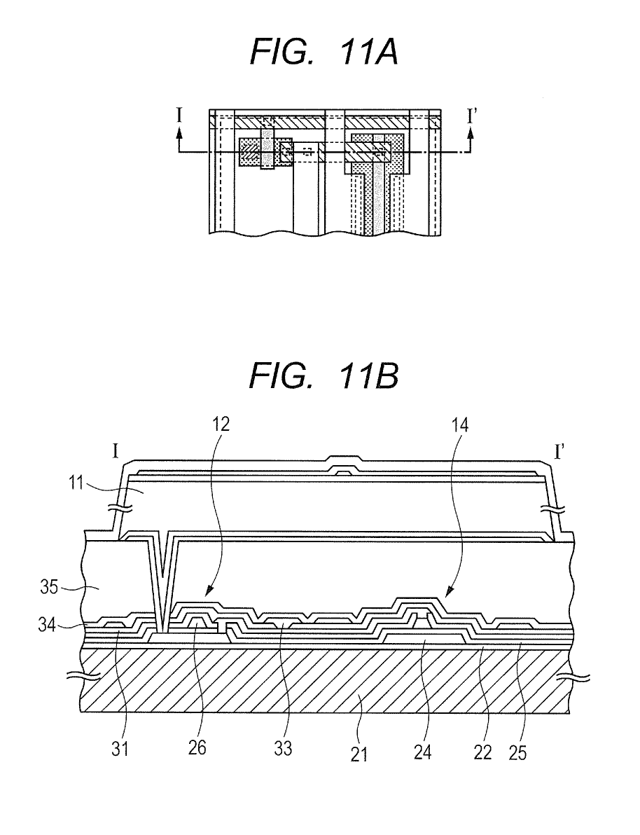

In FIG. 11B, FIG. 11B is a sectional view of the layout of FIG. 2, and corresponds to the cross section taken along a dashed line I-I′ illustrated in FIG. 11A which is a part of FIG. 10. The transfer thin film transistor 12, the reset thin film transistor 13 and the source follower thin film transistor 14 are formed on the upper side of the insulation substrate 21, and the photoelectric conversion element 11 is formed on the upper part thereof through the organic planarized film 35 and the like. Though being not illustrated in FIGS. 11A and 11B, the wavelength conversion element of the electro-magnetic wave such as GOS or CsI exists on the photoelectric conversion element 11.

As has been described above, the present embodiment realizes a highly reliable radiation imaging apparatus which shows an enhanced signal transfer speed even when the signal is transferred through a circuit using the source follower circuit, and can sufficiently cope with the high-speed driving as well.

### Second Embodiment

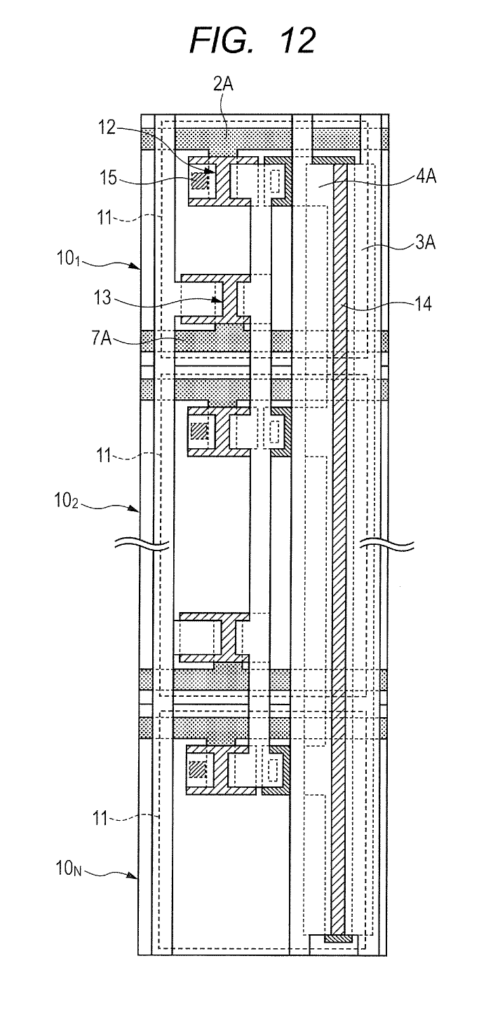

The present embodiment discloses a radiation imaging apparatus as an imaging apparatus, similarly to the case of the first embodiment. Each thin film transistor in the present embodiment is illustrated by an example of a bottom gate type of a thin film transistor which uses amorphous silicon. In addition, the components and the like corresponding to those in the first embodiment will be denoted by the same reference numerals, and the detailed description will be omitted. FIG. 12 is a magnified layout chart illustrating N pieces (N is an arbitrary integer of 3 or more) of adjacent pixel regions in the radiation imaging apparatus according to the present embodiment.

In FIG. 12, the respective pixel regions shall be represented by pixel regions 10₁, 10₂, . . . 10_{N}. Each of the pixel regions 10₁, 10₂, . . . 10_{N} includes a photoelectric conversion element 11, a transfer thin film transistor 12 and a reset thin film transistor 13. Furthermore, one source follower thin film transistor 14 is formed so as to be common in the pixel regions 10₁, 10₂, . . . 10_{N}. The one source follower thin film transistor 14 is arranged so that the gate 14a (and channel portion in lower part) and the source/drain 14b of the source follower thin film transistor 14 are extended over the pixel regions 10a and 10b. In FIG. 12, each contact hole 15 is illustrated.

As the value of N is larger, the flexibility of a layout is more enhanced, the channel width (gate width) of the source follower thin film transistor 14 can be more enlarged, and lower resistance can be realized. For instance, it is understood that if the source follower thin film transistor 14 is formed so as to be extended over approximately 10 pixel regions to 30 pixel regions by assuming that the size for one pixel region is approximately 150 μm and by devising the layout, the radiation imaging apparatus can manage to drive a moving image.

FIG. 13 to FIG. 19 are layout charts illustrating a manufacturing process of the radiation imaging apparatus according to the present embodiment, in order of the steps. Here, only two adjacent pixel regions 10₁ and 10₂ out of N pieces of the adjacent pixel regions 10₁, 10₂, . . . 10_{N} are illustrated.

Firstly, as is illustrated in FIG. 13, a transfer driving line 2A and a reset driving line 7A are film-formed on a cleaned insulation substrate 21. The resistance of the driving line of the thin film transistor may be low, and the film thickness may be approximately 200 nm to 500 nm. The material may be a low resistance metal such as aluminum, copper and neodymium, or may also be an alloy thereof. Next, a first gate insulation film 37 is formed. The material may be silicon nitride (SiN), and the film thickness is desirably set at approximately 200 nm to 400 nm.

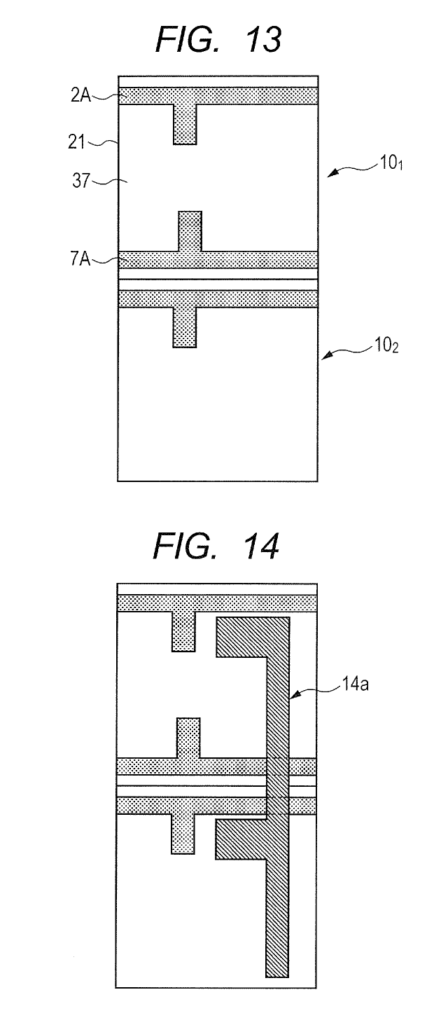

Subsequently, as is illustrated in FIG. 14, an electroconductive material is film-formed and is etched into an island shape to form the gate 14a of the source follower thin film transistor 14. It is determined in this etching process how many pixel regions the source follower thin film transistor 14 is formed so as to be extended over.

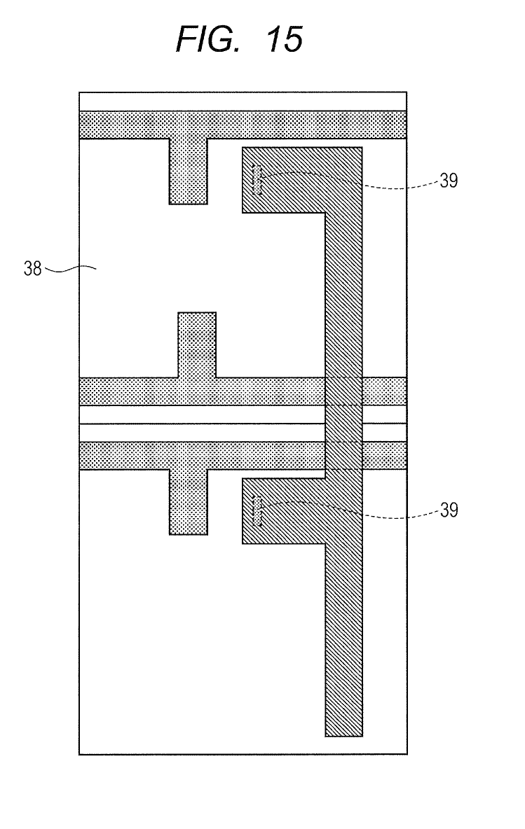

Subsequently, as is illustrated in FIG. 15, a second gate insulation film 38 is formed. The material may be silicon nitride (SiN) similarly to that of the first gate insulation film 37, and the film thickness is desirably set at approximately 200 nm to 400 nm. After that, each contact hole 39 is formed in the second gate insulation film 38 by using a dry etching technology. The contact hole 39 is a hole through which the gate 14a of the source follower thin film transistor 14 is electrically connected with the source of the transfer thin film transistor 12.

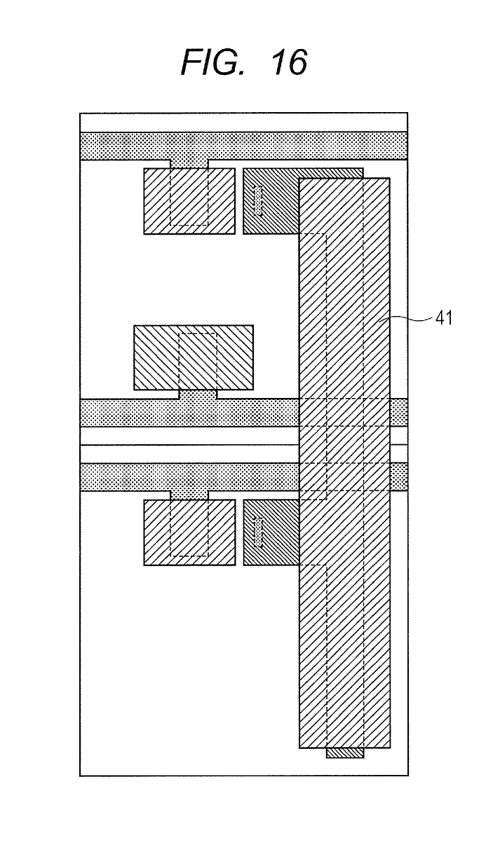

Subsequently, as is illustrated in FIG. 16, amorphous silicon is film-formed, and an impurity semiconductor layer is further film-formed which becomes a source/drain. The amorphous silicon and the impurity semiconductor layer shall be referred to as a film stack 41. The amorphous silicon is used for forming each channel portion of the transfer thin film transistor 12, the reset thin film transistor 13 and the source follower thin film transistor 14. The amorphous silicon is film-formed with a plasma CVD method or the like, and the film thickness may be approximately 100 nm to 200 nm. The impurity semiconductor layer is film-formed with the plasma CVD method or the like, similarly to the method for the amorphous silicon, and the film thickness may be desirably approximately 15 nm to 60 nm. After that, the film stack 41 is etched into an island shape.

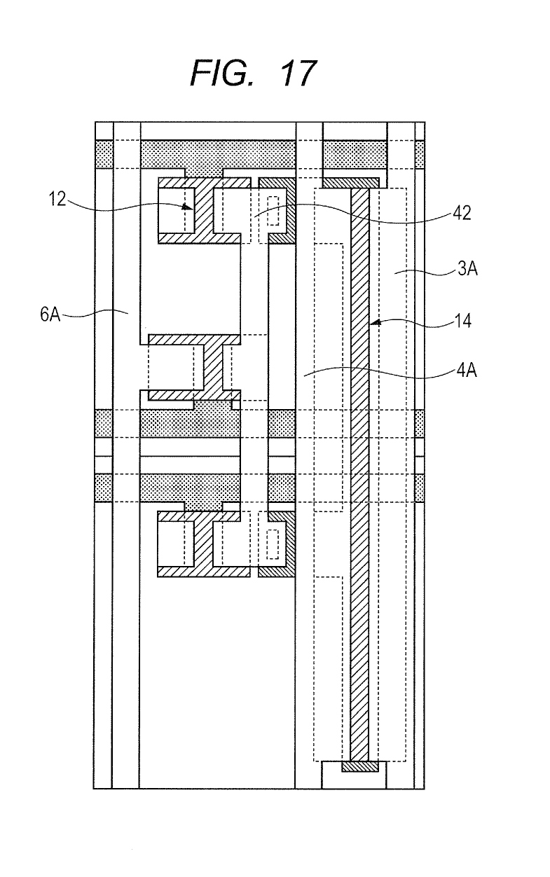

Subsequently, as is illustrated in FIG. 17, a low-resistance metal layer 42 is film-formed by film-forming and etching the metal layer. After that, the impurity semiconductor layer which is film-formed in the upper part of the film stack 41 is formed by etching the impurity semiconductor layer while using the low-resistance metal layer 42 as a mask. By this low-resistance metal layer 42, a signal line 3A, a source voltage supply line 4A and a reset potential supply line 6A are formed which are connected to the source follower thin film transistor 14. Furthermore, the drain of the transfer thin film transistor 12 and the gate of the source follower thin film transistor 14 are connected to each other.

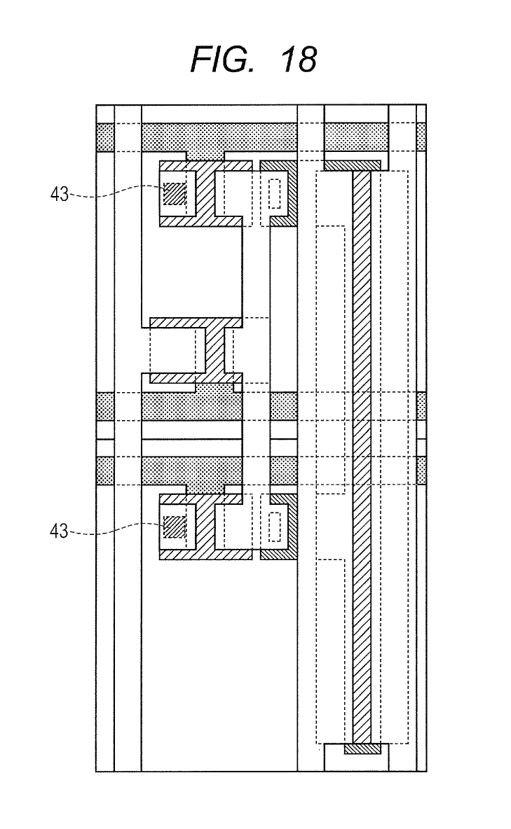

Subsequently, as is illustrated in FIG. 18, a protection layer of the thin film transistors 12, 13 and 14 is film-formed. The protection layer may be film-formed from silicon nitride (SiN), and the film thickness may be approximately 200 nm to 700 nm. After that, a contact hole for connecting the drain of the transfer thin film transistor 12 with the photoelectric conversion element 11 which will be film-formed later is formed in the protection layer. Next, an organic planarized film is formed in order to decrease the parasitic capacitances of the thin film transistors 12, 13 and 14 and the photoelectric conversion element 11. The film thickness is desirably approximately 3.5 μm to 5 μm.

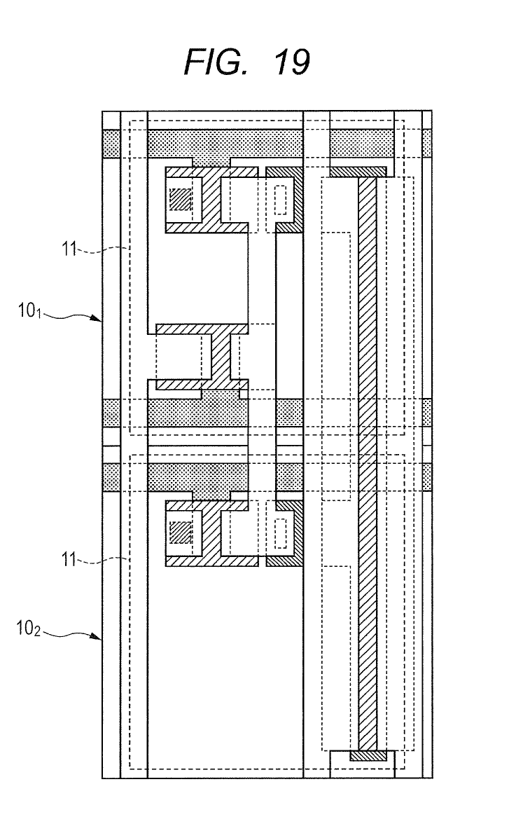

Subsequently, as is illustrated FIG. 19, the material of the photoelectric conversion element is film-formed, the film is separated on a space between the pixel regions by etching, and the photoelectric conversion element 11 is formed. A common electrode line 5A and the like are connected to the photoelectric conversion element 11. The photoelectric conversion element 11 is formed of the PIN type. In addition, a protection film such as SiN, and a GOS or CsI which is a wavelength conversion element are arranged on the photoelectric conversion element 11. By the above steps, the radiation imaging apparatus having a layout illustrated in FIG. 12 is formed.

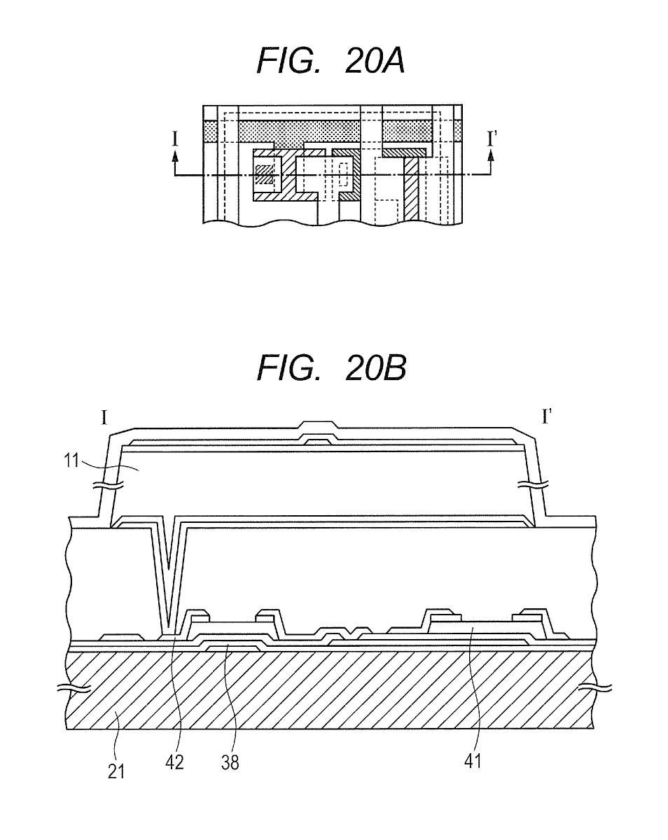

In FIG. 20B, FIG. 20B is a sectional view of the layout of FIG. 12, and corresponds to the cross section taken along a dashed line I-I′ illustrated in FIG. 20A which is a part of FIG. 19. The transfer thin film transistor 12, the reset thin film transistor 13 and the source follower thin film transistor 14 are formed on the upper side of the insulation substrate 21, and the photoelectric conversion element 11 is formed on the upper part thereof through the organic planarized film 35 and the like. Though being not illustrated in FIGS. 20A and 20B, the wavelength conversion element of the electro-magnetic wave such as GOS or CsI exists on the photoelectric conversion element 11.

As has been described above, the present embodiment realizes a highly reliable radiation imaging apparatus which shows an enhanced signal transfer speed even when the signal is transferred through a circuit using the source follower circuit, and can sufficiently cope with the high-speed driving as well.

### Third Embodiment

The present embodiment discloses a radiation imaging apparatus as an imaging apparatus, similarly to the case of the second embodiment. Each thin film transistor in the present embodiment is illustrated by an example of a bottom gate type of a thin film transistor which uses amorphous silicon. In addition, the components and the like corresponding to those in the first and second embodiments will be denoted by the same reference numerals, and the detailed description will be omitted.

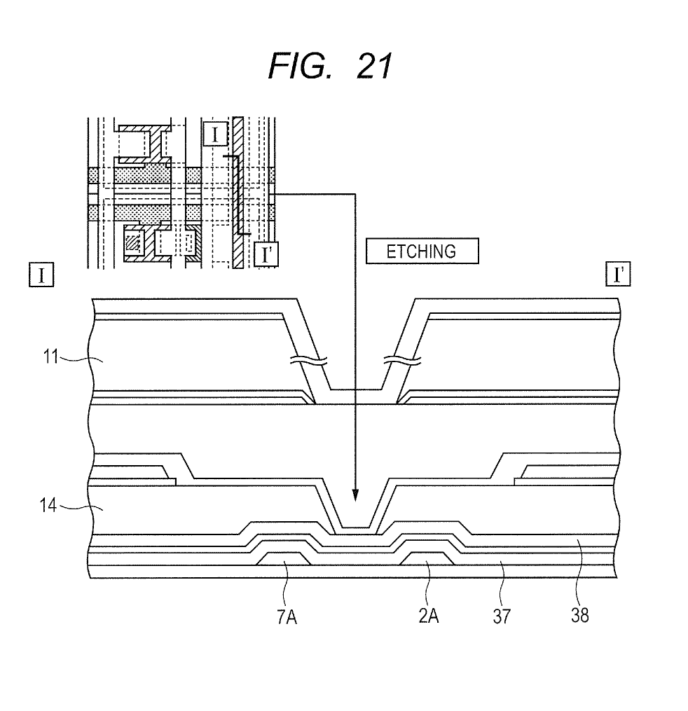

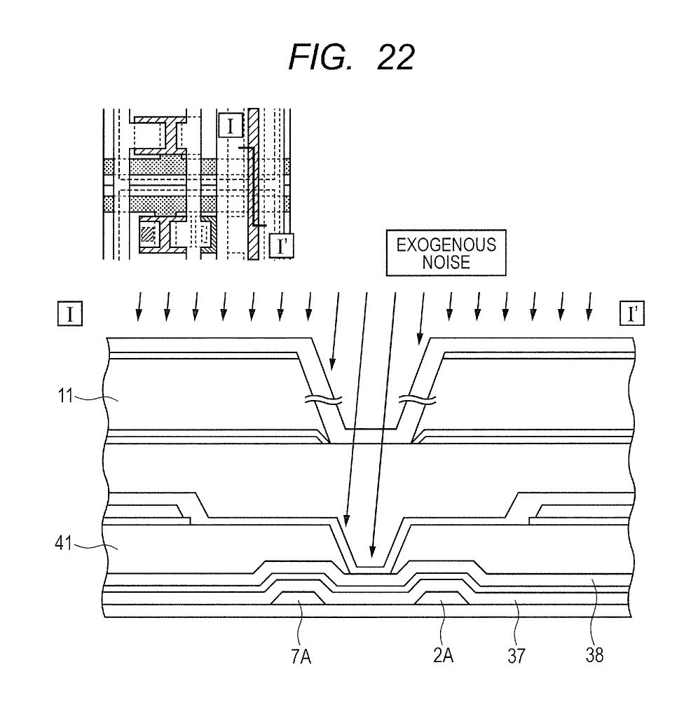

FIG. 21 is a representative layout chart of a radiation imaging apparatus according to the present embodiment. Similarly to the case of the second embodiment, when the source follower thin film transistor 14 is formed so as to be extended over the plurality of the pixel regions, there exist a part having the pixel region in its upper part and a part (portion between adjacent pixel regions) having no pixel region on its upper part. A threshold value of the source follower thin film transistor 14 is different between the former part and the latter part. As is illustrated in FIG. 22, the photoelectric conversion element 11 has also a function of protecting the channel portion of the source follower thin film transistor 14 from an exogenous noise such as an electro-magnetic wave. In other words, sensitivities of the source follower thin film transistor 14 with respect to the exogenous noise are different between the portion having the photoelectric conversion element 11 exist on its upper part and the portion having no photoelectric conversion element 11 existing on its upper part, and as a result, the threshold values are different between the portions. If the threshold value varies in the one source follower thin film transistor 14 depending on the portions, the reliability concerning whether the obtained signal truly reflects the light-receiving information or not is lowered.

In the present embodiment, as is illustrated in FIG. 21, the channel portion (amorphous silicon 41) of the source follower thin film transistor 14 is etched in the following way. In other words, in the channel portion, the part (portion between adjacent pixel regions) having no photoelectric conversion element 11 existing on its upper portion, in other words, a part which becomes a path for charge transfer, is partially removed by etching. This structure enables the imaging apparatus to read the signal without causing the dispersion of the threshold value and the like and without impairing the information of the photoelectric conversion element 11, even when the source follower thin film transistor 14 is formed so as to be extended over a desired plural number of the pixel regions.

Incidentally, in place of a method of etching a predetermined part of the channel portion of the source follower thin film transistor 14 as in the present embodiment, the source follower thin film transistor 14 may be etched in the following way. In other words, the part (portion between adjacent pixel regions) may be etched which has no photoelectric conversion element 11 existing on its upper portion, in the source/drain of the source follower thin film transistor 14. In addition, it is also possible to form a metal layer in the upper portion of the part having no photoelectric conversion element 11 existing in its upper part, in the channel portion of the source follower thin film transistor 14, and shield the light to the part which becomes the path for charge transfer, by this metal layer.

In addition, in FIG. 2 of the first embodiment and in FIG. 12 of the second embodiment, there is a portion at which the channel portion of the source follower thin film transistor 14 crosses a transfer driving line 2A and a reset driving line 7A, on the upper part of the transfer driving line 2A and the reset driving line 7A. In this portion, it is considered that the switch of the source follower thin film transistor 14 results in turning on when a voltage is applied to each of the thin film transistors, and that the charge is transferred. In order to prevent this phenomenon, the intersection (crossing position) may be etched and removed at which the source/drain of the source follower thin film transistor 14 intersects with the transfer driving line 2A and the reset driving line 7A.

As has been described above, the imaging apparatus according to the present embodiment shows an enhanced transfer speed of the signal even when the signal is transferred through a circuit using the source follower circuit and can sufficiently cope with the high-speed driving as well. Thereby, a highly reliable radiation imaging apparatus is realized which can surely read a signal without impairing the information of the photoelectric conversion element 11.

### Fourth Embodiment

The present embodiment discloses an X-ray diagnosis system as a radiation imaging system provided with one type of a radiation imaging apparatus selected from first to third embodiments.

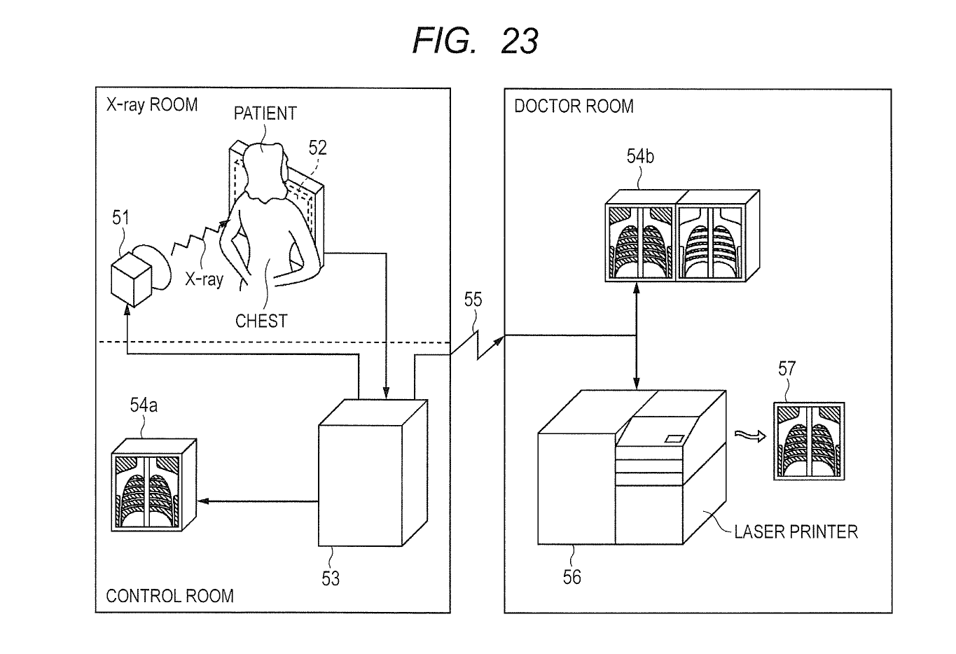

FIG. 23 is a schematic view illustrating a schematic configuration of an X-ray diagnosis system according to the present embodiment.

This X-ray diagnosis system includes an X-ray tube 51, a photoelectric conversion apparatus 52, an image processor 53, displays 54a and 54b, a telephone line 55 and a film processor 56. The X-ray tube 51 is a radiation source for generating an electro-magnetic wave which is X-rays here. The photoelectric conversion apparatus 52 has a scintillator mounted on its upper part, and is one type of a radiation imaging apparatus selected from the first to third embodiments. The image processor 53 is a signal processing unit for digitizing a signal which has been output from the photoelectric conversion apparatus 52. The displays 54a and 54b are display units for displaying signals which have been output from the image processor 53. The telephone line 55 is a transfer processing unit for transferring the signals which have been output from the image processor 53 to a remote place such as a doctor room that is another place. The film processor 56 is a recording unit for recording the signals which have been output from the image processor 53.

When this X-ray diagnosis system is used, X-rays which have been generated in an X-ray tube 51 transmit through a chest of a patient (subject), and is incident on the photoelectric conversion apparatus 52 which has the scintillator mounted on its upper part. Here, the photoelectric conversion apparatus 52 having the scintillator mounted on its upper part constitutes one type of a radiation imaging apparatus selected from the first to fourth embodiments. These incident X-rays include the information of the inside of the body of the patient. The scintillator emits light in response to the incident X-rays, and the photoelectric conversion apparatus converts the light to an electric signal to obtain electric information. This information is converted into digital signals, the signals are processed into an image by the image processor 53 which becomes a signal processing unit, and the image can be observed through the display 54a which becomes a display unit of a control room.

In addition, this information can be transferred to a remote place through a transfer processing unit such as the telephone line 55, can be displayed on the display 54b which becomes a display unit in the doctor room or the like that is another place, or can be stored in a recording unit such as an optical disk. Based on the information, a doctor in the remote place can also diagnose the disease. In addition, the information can be also recorded on a film 57 which becomes a recording medium, by the film processor 56 that becomes a recording unit.

As has been described above, the present embodiment realizes a highly reliable X-ray diagnosis system which shows an enhanced signal transfer speed even when the signal is transferred through a circuit using the source follower circuit, can sufficiently cope with the high-speed driving as well, and can take images in a desired moving image mode and a desired still picture mode.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-279752, filed Dec. 21, 2011, which is hereby incorporated by reference herein in its entirety.

What is claimed is:

1. An imaging apparatus comprising:
a plurality of pixels, each including a conversion element and a first transistor, wherein one of a source and a drain of the first transistor is connected to the conversion element; and
a second transistor being shared by the plurality of pixels and having a gate connected respectively to the other of the source and the drain of the first transistor of each of the plurality of pixels, wherein
at least one among the gate, a source, a drain and a channel portion of the second transistor is formed to be extended over the plurality of pixels, and the conversion element is arranged over the first and second transistors.

2. The imaging apparatus according to claim 1, wherein
the second transistor is partially removed at a part of the channel portion over which the conversion element is not arranged.

3. The imaging apparatus according to claim 1, wherein
the second transistor is partially removed at a part of the source and/or the drain over which the conversion element is not arranged.

4. The imaging apparatus according to claim 2, wherein
the part removed is positioned at an intersection between a driving line of the first transistor and the second transistor.

5. The imaging apparatus according to claim 3, wherein
the part removed is positioned at an intersection between a driving line of the first transistor and the second transistor.

6. The imaging apparatus according to claim 2, wherein a metal layer is formed at a position of the channel portion of the second transistor over which the conversion element is not arranged.

7. The imaging apparatus according to claim 1, wherein
the first transistor and the second transistor have a top gate structure formed using a poly-silicon.

8. The imaging apparatus according to claim 1, wherein
the first transistor and the second transistor have a bottom gate structure formed using a amorphous-silicon.

9. A radiation imaging system comprising:
an imaging apparatus according to claim 1; and
a signal processing unit for processing a signal outputted from the imaging apparatus.

10. The imaging system according to claim 9, further comprising
a recording unit for recording a signal outputted from the signal processing unit;
a radiation source generating an electro-magnetic wave;
a display unit for displaying based on the signal outputted from the signal processing unit; and
a transfer processing unit for transferring a signal outputted from the signal processing unit.

11. A manufacturing method of an imaging apparatus comprising:
a plurality of pixels, each including a conversion element and a first transistor, wherein one of a source and a drain of the first transistor is connected to the conversion element, wherein the method comprising steps of:
forming a second transistor being shared by the plurality of pixels and having a gate connected respectively to the other of the source and the drain of the first transistor of each of the plurality of pixels, such that at least one among the gate, a source, a drain and a channel portion of the second transistor is extended over the plurality of pixels; and
forming the conversion element over the first and second transistors.
